(19) United States
(12) Patent Application Publication
(10) Pub. No.: US 2011/0132884 A1
(43) Pub. Date: Jun. 9, 2011

(54) LASER MODULES AND PROCESSES FOR THIN FILM SOLAR PANEL LASER SCRIBING

(75) Inventors: Antoine P. Manens, Sunnyvale, CA (US); Wei-Sheng Lei, San Jose, CA (US); Wei-Yung Hsu, San Jose, CA (US); Bassam Shamoun, Fremont, CA (US); Yan Wang, Sunnyvale, CA (US)

(73) Assignee: Applied Materials, Inc., Santa Clara, CA (US)

(21) Appl. No.: 12/851,442

(22) Filed: Aug. 5, 2010

Related U.S. Application Data
(60) Provisional application No. 61/231,968, filed on Aug. 6, 2009.

(51) Int. Cl. B23K 26/00

(52) U.S. Cl. 219/121.72; 219/121.67

(57) ABSTRACT

Laser systems for laser scribing are provided. The systems include a remote module coupled to a laser module through a cable. The remote module includes a controller and a chiller. The laser module has at least a laser source and a cooling plate. The laser module is operable to remove material from at least a portion of a workpiece. The systems also include a plurality of termination modules coupled to the laser module through a plurality of optical fibers. Each of the termination modules includes a mechanical interface. The mechanical interface is coupled to a respective optical fiber. The systems further include a plurality of scanning devices operable to control a position of the output from the laser. Each of the scanning devices is coupled to a respective mechanical interface.

### CROSS-REFERENCES TO RELATED APPLICATIONS

This application claims the benefit of U.S. Prov. Patent Application No. 61/231,968 filed Aug. 6, 2009, and titled “LASER MODULES AND PROCESSES FOR THIN FILM SOLAR PANEL LASER SCRIBING” and incorporated herein by reference for all purposes.

### BACKGROUND OF THE INVENTION

Many embodiments described herein relate generally to laser modules and methods for scribing materials, such as materials for thin film solar panels. Various embodiments also relate to optical fiber delivery of laser power to scanning devices and effective reduction in thermal loading to the laser modules. These systems and methods can be particularly effective in scribing single junction solar cells and thin-film multi junction solar cells.

Current methods for forming thin-film solar cells involve depositing or otherwise forming a plurality of layers on a substrate, for example, a glass, metal or polymer substrate suitable to form one or more p-n junctions. An example of a solar cell has an oxide layer (e.g., a transparent conductive oxide (TCO)) deposited on a substrate, followed by an amorphous-silicon layer and a metal-back layer. Examples of materials that can be used to form solar cells, along with methods and apparatus for forming the cells, are described, for example, in U.S. Pat. No. 7,582,515, issued Sep. 1, 2009,entitled “MULTI-JUNCTION SOLAR CELLS AND METHODS AND APPARATUSES FOR FORMING THE SAME,” which is hereby incorporated herein by reference. When a panel is being formed from a large substrate, a series of scribe lines is typically used within each layer to delineate the individual cells. The scribe lines are formed by laser ablating material from a workpiece, which consists of a substrate having at least one layer deposited thereon. The laser-scribing process may occur with the workpiece sitting supported on top of a planar stage or bed.

Laser-scribed patterns are formed on the workpiece by having relative motion between the laser beam and the workpiece. In previous approaches, this is accomplished by having the laser beam fixed and moving the workpiece. If the workpiece is held stationary on the stage or bed, then this would involve moving the stage or bed. If the workpiece has some degree of freedom to move on the stage or bed, then this would involve some combination of moving the workpiece and/or moving the stage or bed. Also, if the workpiece moves relative to a fixed laser then the bed might have to be up to four times the size of the workpiece, or the workpiece must be rotated, in order to access all areas of the workpiece. Further, under this fixed laser beam approach, the beam path from the scribing laser to the workpiece can be long. This long fixed beam path between the laser and the workpiece raises beam convergence and stability issues. Further, the stage or bed can consists of a single planar piece that holds the workpiece stationary and moves together with the workpiece. In order to accommodate the workpieces, which in one example can be as large as one square meter, this stage also has to be large, making it difficult to ship from the manufacturer site to the user site.

In recent development, systems and methods are provided for scribing of patterns in two dimensions on the workpiece without rotating the workpiece. For example, the system includes a translation stage operable to support the workpiece and translate the supported workpiece in a longitudinal direction, a laser system operable to generate output able to remove material from at least a portion of the workpiece, a scanning device operable to control a position of the output from the laser system, and a controller. The controller is coupled with the translation stage, the laser system, and the scanning device. The controller is operable to coordinate a position of the translation stage with the generation of an output from the laser system and with a scanned position of the output from the laser system. For precision laser scribing, it is important to have small footprint of the laser system and a good thermal control of the laser system.

Processes such as scribing or ablation can be performed on the workpiece using relative motion between the active portion of the tool, such as at least one laser beam, and the workpiece. This is typically accomplished by at least moving the workpiece on the stage. Problems can occur, however, as large workpieces can tend to bend due to forces such as gravity and clamping stress. Further, devices used to support the workpiece such as rollers or bearings can cause particles to become attached to the workpiece, which can lead to processing problems. Further, in certain tools the workpiece can rub or otherwise come into contact with portions of the tool that can scratch or otherwise damage the workpiece.

During the laser scribing processes, static discharge may be built on the workpiece. Such static discharge may cause some scribed materials or contamination adhere to the workpiece such that it may be difficult to exhaust the scribed materials by the current exhaust mechanism.

When scribing lines are formed on the workpiece during the laser scribing processes, it is desirable to monitor the quality of the scribed lines. An image system may be integrated with the system to view the quality of scribed lines. However, this image is collected after scribing, not during scribing. It is important to obtain quick feedback information for better process control. The scribing lines may contain gaps or improperly scribed. Monitoring electrical isolation of the scribed lines is also important to ensure the quality of laser scribing.

Accordingly, it is desirable to develop systems and methods that overcome at least some of these, as well as potentially other, deficiencies in existing scribing and solar panel manufacturing devices. More specifically, it is desirable to provide a small footprint of the laser system and a mechanism for minimizing thermal loading to the laser system to provide more stable temperature control of the laser system. It is also desirable to improve beam size consistency and laser pointing stability. Furthermore, it is desirable to provide in-situ monitoring systems and methods for better monitoring of the laser scribing lines. It is still desirable to provide a mechanism for minimizing damage or contamination of a workpiece during processing as a result of the movement or support of the workpiece in a tool or other such device. It is still yet desirable to provide a mechanism to reduce static discharge on the workpiece.

### BRIEF SUMMARY OF THE INVENTION

The following presents a simplified summary of some embodiments of the invention in order to provide a basic understanding. This summary is not an extensive overview of the various embodiments, and is not intended to identify key/critical elements or to delineate the scope of those embodiments. Its sole purpose is to present some embodiments in a simplified form as a prelude to the more detailed description that is presented later.

Systems and methods for laser scribing a workpiece with fiber delivery of laser power to scanners and a central remote module for providing control, power supply, and cooling to laser sources are provided. Many embodiments may provide for improved thermal control and beam quality, reduction of static discharge, as well as the ability to monitor electrical isolation of scribed lines on the workpiece. Systems and methods in accordance with many embodiments provide for general purpose, high-throughput, direct patterning laser scribing on large film-deposited substrates. These systems and methods may be particularly effective in scribing single junction solar cells and thin-film multi junction solar cells.

In many embodiments, a laser system for scribing a workpiece is provided. The laser system for laser scribing includes a remote module coupled to the laser module through a cable. The remote module includes a controller, a chiller, and a power supply. The laser system includes a laser module comprising a laser source and a cooling plate. The laser module is operable to remove material from at least a portion of a workpiece. The laser system also includes a plurality of termination modules coupled to the laser module through a plurality of optical fibers. Each of the termination modules includes a mechanical interface. The mechanical interface is coupled to a respective optical fiber. The laser system further includes a plurality of scanning devices operable to control a position of the output from the laser. Each of the scanning devices is coupled to a respective mechanical interface.

In another embodiment, a different laser system for laser scribing is provided. The system includes a remote module coupled to the plurality of laser modules through a cable. The remote module includes a controller and a chiller. The system includes a plurality of laser modules. Each of the laser modules includes a laser source and a cooling late. The laser modules are operable to remove material from at least a portion of a workpiece. The system also includes a plurality of termination modules coupled to the plurality of laser modules through a plurality of optical fibers. Each of the termination modules includes a mechanical interface. The mechanical interfaces are coupled to the respective optical fiber. The system further includes a plurality of scanning devices operable to control a position of the output from the laser. Each of the scanning devices is coupled to the respective mechanical interface.

In an alternative embodiment, a laser system for laser scribing is provided. The system includes at least one laser module operable to remove material from at least a portion of a workpiece. The system also includes at least one scanning device operable to control a position of the output from the laser module. The system further includes a resistance measurement device for resistance measurement operable to be coupled to the workpiece for in-situ measurement of electrical isolation of scribed lines on the workpiece.

In a further embodiment, a laser system for laser scribing is provided. The system includes at least one laser module operable to remove material from at least a portion of a workpiece. The system also includes at least one scanning device operable to control a position of the output from the laser module. The system further includes a discharge mechanism adjacent to at least one of the scanning device and the workpiece. The discharge mechanism is operable to discharge a surface of the workpiece.

In a still yet further embodiment, a method for fabricating a solar-cell assembly is provided. The method includes providing a workpiece comprising a substrate and at least one layer including scribed interconnect lines. The method also includes scribing a plurality of isolation lines into at least one layer, measuring electrical isolation resistance of at least one of the plurality of isolation lines, and determining if the electrical isolation resistance at least meets a threshold. Moreover, the method includes re-scribing a portion of the each measured isolation lines if the electrical isolation resistance is below the threshold.

### BRIEF DESCRIPTION OF THE DRAWINGS

A further understanding of the nature and advantages of the invention may be realized by reference to the remaining portions of the specification and the drawings wherein like reference numerals are used throughout the several drawings to refer to similar components. The Figures are incorporated into the detailed description portion of the invention.

FIG. 1 illustrates laser-scribed lines in a thin-film solar-cell assembly.

FIG. 2 illustrates a perspective view of a laser-scribing system in accordance with many embodiments.

FIG. 3 illustrates a side view of a laser-scribing system in accordance with many embodiments.

FIG. 4 illustrates an end view of a laser-scribing system in accordance with many embodiments.

FIG. 5 illustrates a top view of a laser-scribing system in accordance with many embodiments.

FIG. 6 illustrates a set of laser assemblies in accordance with many embodiments.

FIG. 7 illustrates components of a laser assembly in accordance with many embodiments.

FIG. 8 illustrates the generation of multiple scan areas in accordance with many embodiments.

FIG. 9 diagrammatically illustrates the integration of a camera within a laser-scanning assembly in accordance with many embodiments.

FIG. 10 illustrates a laser scribing system having a remote box connected to a single laser source in accordance with many embodiments.

FIG. 11 illustrates a laser scribing system having a central remote box connected to multiple laser sources in accordance with many embodiments.

FIG. 12 illustrates the use of line sensing optics to align the formation of a laser-scribed line with a previously formed laser-scribed line in accordance with many embodiments.

FIG. 13 illustrates the use of a beam viewer to measure the position of a laser beam in accordance with many embodiments.

FIG. 14A illustrates a device for measuring electrical isolation of scribed lines.

FIG. 14B illustrates an in-situ measurement device integrated within a laser scribing system for measuring electrical isolation of scribed lines.

FIG. 15 illustrates the integration of a discharge mechanism within a laser scribing system.

### DETAILED DESCRIPTION OF THE INVENTION

Systems and methods in accordance with many embodiments of the present disclosure can overcome one or more of the aforementioned and other deficiencies in existing scribing approaches. Many embodiments can provide for improved control as well as the ability to scribe in multiple directions and/or patterns without rotating a substrate. Systems and methods in accordance with many embodiments provide for general purpose, high-throughput, direct patterning laser scribing on large film-deposited substrates. Such systems and methods allow for bi-directional scribing, patterned scribing, arbitrary pattern scribing, and/or adjustable pitch scribing, without having to rotate a workpiece.

Systems and methods in accordance with many embodiments provide for laser scribing using simple longitudinal glass movement and multiple laser scanners to scribe workpieces, for example, film-deposited substrates used in some solar cell devices. The workpiece can be moved during scribing, and lasers direct beams to translatable scanners that direct the beams up through the substrate to the film(s) being scribed. The scanners can provide for both latitudinal and longitudinal scribing.

Many embodiments can provide for a relatively short beam path from the scribing laser to the workpiece, which may significantly alleviate any beam convergence and stability issues. In many embodiments, a shorter beam path from the scribing laser to the workpiece is realized by having the laser source close to the workpiece. In many embodiments, this beam path is made even shorter by having the laser source move laterally according to the pattern the laser is trying to scribe. Allowing the laser source to be close to the workpiece allows the laser beam path to be minimized, which may help to minimize issues such as beam convergence and stability. In many embodiments, the workpiece moves longitudinally and the laser beam is able to move both laterally and longitudinally via a scanning device, but the laser beam path is still minimized as the laser source moves using a translation mechanism able to laterally translate the laser assemblies relative to the workpiece.

In many embodiments, a translation stage or bed is implemented with separated sections, such as substantially planar sections. In many embodiments, the center section is laterally movable, allowing the center section of the bed to move in conjunction with the laser source and optics as laterally translated by the translation mechanism, allowing a desired pattern to be scribed on the workpiece, while the two end sections of the bed are kept stationary. Such coordinated motion also provides various other advantages as described elsewhere herein. In many embodiments, the translation stage or bed consists of three or more sections that allow the base of the bed to be shipped in three or more parts using different packaging levels and assembled on site, making it easier to ship from the manufacturer site to the user site.

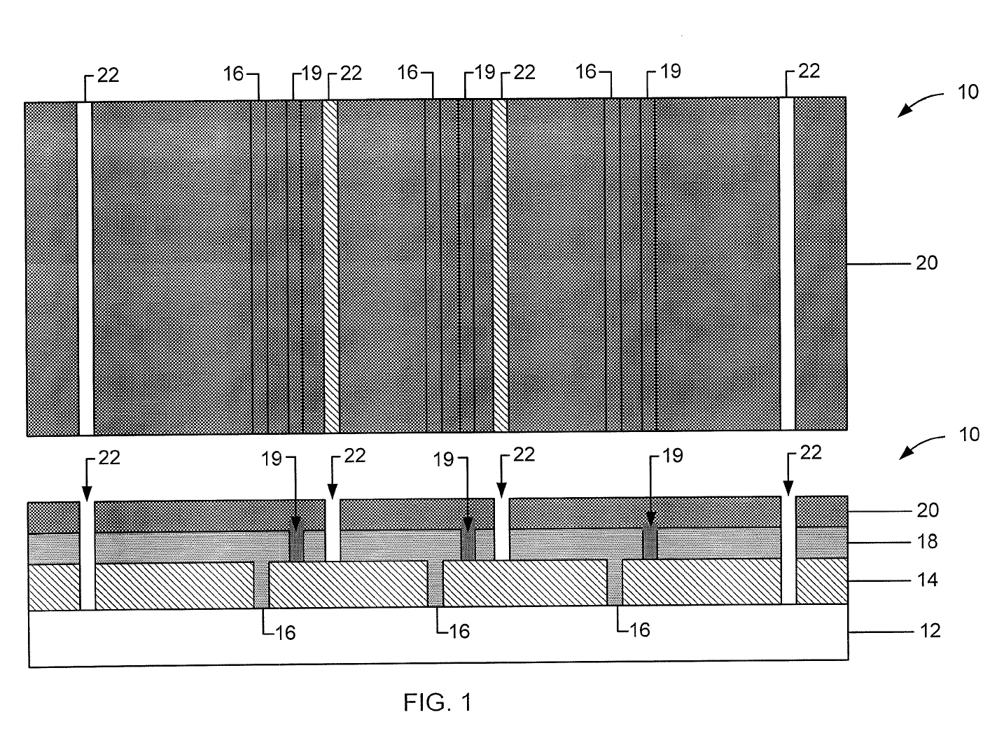

When a solar panel is being formed from a large substrate, for example, a series of laser-scribed lines can be used within each layer to delineate the individual cells. FIG. 1 illustrates laser-scribed lines within an example assembly 10 used in a thin-film solar cell. During the formation of the assembly 10, a glass substrate 12 has a transparent conductive oxide (TCO) layer 14 deposited thereon. The TCO layer 14 is then separated into isolated regions via laser-scribed P1 lines 16. Next, an amorphous-silicon (a-Si) layer 18 is deposited on top of the TCO layer 14 and within the scribed P1 lines 16. A second set of lines (“P2” lines 19) are then laser scribed in the amorphous-silicon (a-Si) layer 18. A metal-back layer 20 is then deposited on top of the amorphous-silicon (a-Si) layer 18 and within the scribed P2 lines 19. A third set of lines 22 (“P3” lines) are laser scribed as shown. While much of the area of the resultant assembly constitutes active regions of solar cells of the panel, various regions lying between the P1 16 and P3 22 scribe lines constitute non-active solar-cell area, also known as “the dead zone”.

In order to optimize the efficiency of these solar cell panels, the non-active solar cell area (i.e., the “dead zone”) of these panels should be minimized. To minimize the dead zone, each P3 line 22 should be aligned as close as possible to a corresponding P1 line 16. As will be discussed in more detail below, line sensing optics can be used to adjust the scribing of lines to minimize the dead zone area on the assembly 10.

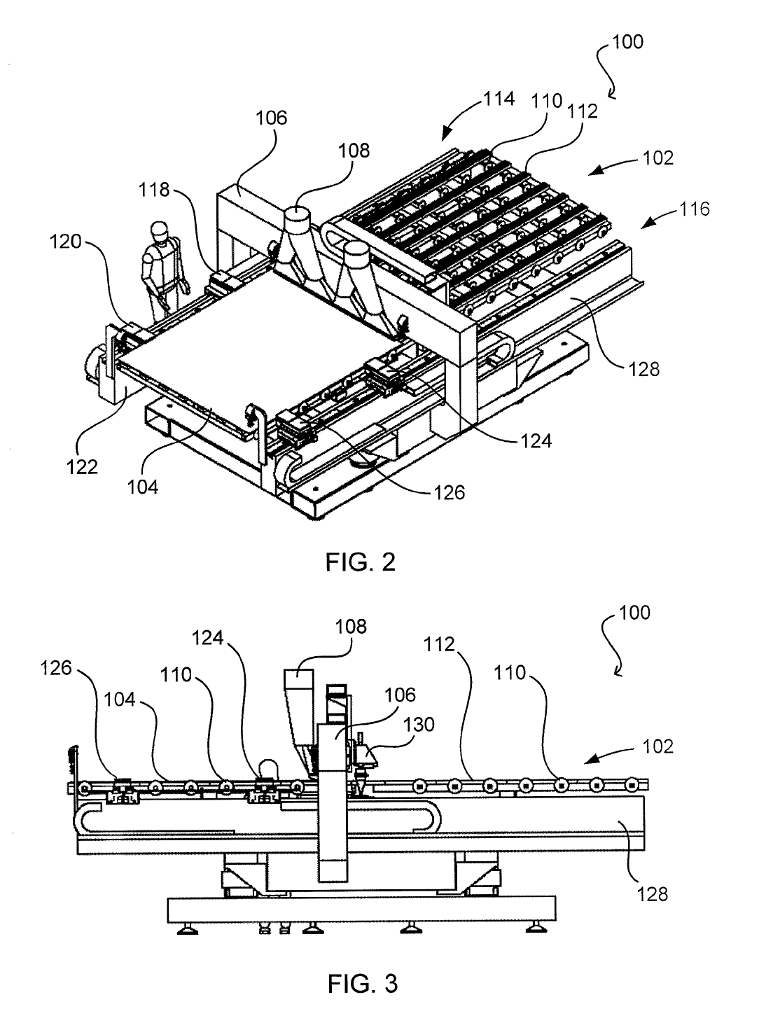

FIG. 2 illustrates an example of a laser-scribing system 100 in accordance with many embodiments. The system includes a translation stage or bed 102, as described herein, which may be leveled, for receiving and maneuvering a workpiece 104, for example, a substrate having at least one layer deposited thereon. In one example, the workpiece 104 is able to move along a single directional vector (i.e., for a Y-stage) at various rates (e.g., from 0 m/s to 2 m/s or faster). In many embodiments, the workpiece will be aligned to a fixed orientation with the long axis of the workpiece substantially parallel to the motion of the workpiece in the device, for reasons described elsewhere herein. The alignment can be aided by the use of cameras or imaging devices that acquire marks on the workpiece. In this example, the lasers and optics (shown in subsequent figures) are positioned beneath the workpiece and opposite a bridge 106 holding part of an exhaust mechanism 108 for extracting material ablated or otherwise removed from the substrate during the scribing process. The workpiece 104 can be loaded onto a first end of the stage 102 with the substrate side down (towards the lasers) and the layered side up (towards the exhaust). The workpiece is initially received onto an array of rollers 110 and can then be supported by a plurality of parallel air bearings 112 for supporting and allowing translation of the workpiece, although other bearing- or translation-type objects can be used to receive and translate the workpiece as known in the art. In this example, the array of rollers all point in a single direction, along the direction of propagation of the substrate, such that the workpiece 104 can be moved back and forth in a longitudinal direction relative to the laser assembly.

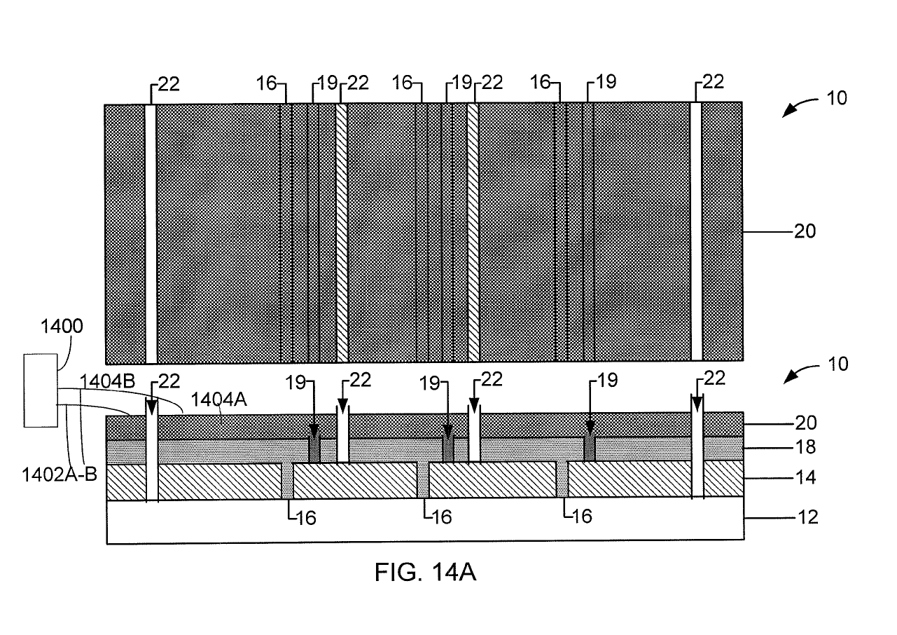

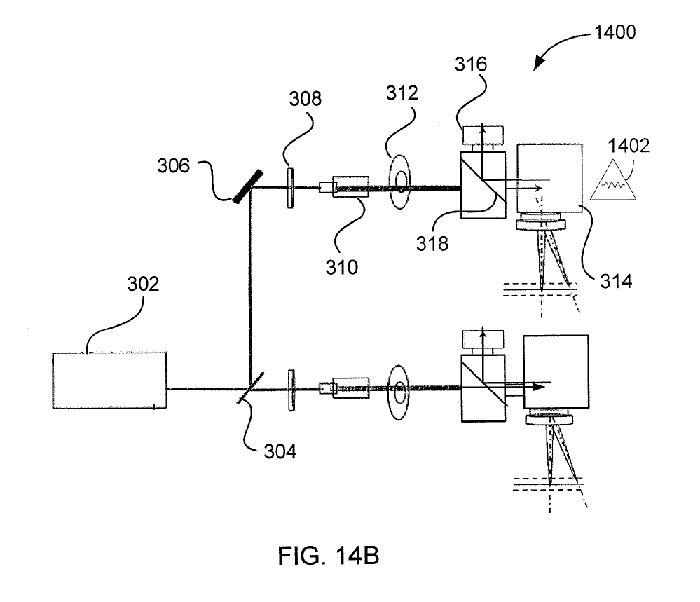

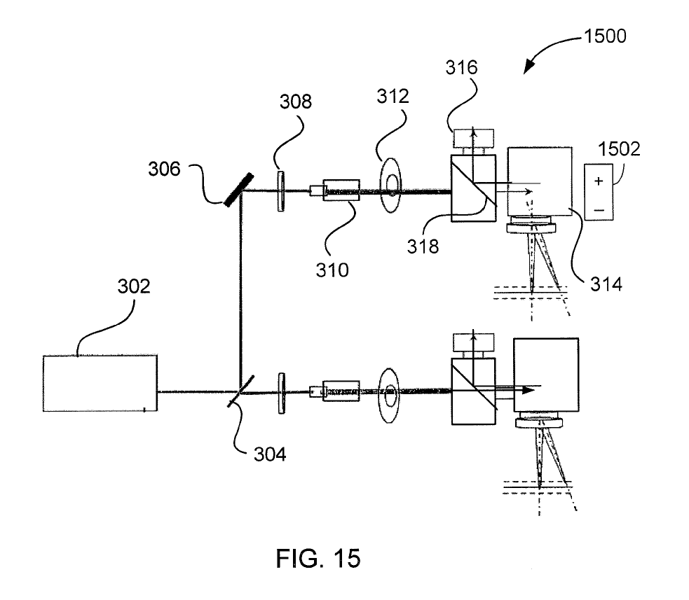

The system 100 includes a controllable drive mechanism for controlling a direction and translation velocity of the workpiece 104 on the stage 102. The controllable drive mechanism includes two Y-direction stages, a stage Y1 114 and stage Y2 116, disposed on opposite sides of the workpiece 104. The stage Y1 114 includes two X-direction stages (stage XA1 118 and stage XA2 120) and a Y1-stage support 122. The stage Y2 116 includes two X-direction stages (stage XB1 124 and stage XB2 126) and a Y2-stage support 128. The four X-direction stages 118, 120, 124, 126 include workpiece grippers for holding the workpiece 104. Each of the Y-direction stages 114, 116 include one or more air bearings, a linear motor, and a position sensing system. As will be described in more detail below with reference to FIGS. 14 and 15, the X-direction stages 118, 120, 124, 126 provide for more accurate workpiece movement by correcting for straightness variations that exist in the Y-direction stage supports 122, 128. The stage 102, bridge 106, and the Y-stage supports 122, 128, can be made out of at least one appropriate material, for example, the Y-stage supports 122, 128 of granite.

The movement of the workpiece 104 is also illustrated in the side view of the system 100 shown in FIG. 3, where the workpiece 104 moves back and forth along a vector that lies in the plane of the figure. Reference numbers are carried over between figures for somewhat similar elements for purposes of simplicity and explanation, but it should be understood that this should not be interpreted as a limitation on the various embodiments. As the workpiece is translated back and forth on the stage 102 by the Y-direction stages, a scribing area of the laser assembly effectively scribes from near an edge region of the substrate to near an opposite edge region of the substrate. The translation of the workpiece is facilitated in part by the movement of the stage Y2 (i.e., by the movement of X-direction stages 124, 126 along the Y2-stage support 128).

In order to ensure that the scribe lines are being formed properly, additional devices can be used. For example, an imaging device can image at least one of the lines after scribing. Further, a beam profiling device 130 can be used to calibrate the beams between processing of substrates or at other appropriate times. In many embodiments where scanners are used, for example, which may drift over time, a beam profiler allows for calibration of the beam and/or adjustment of a beam position.

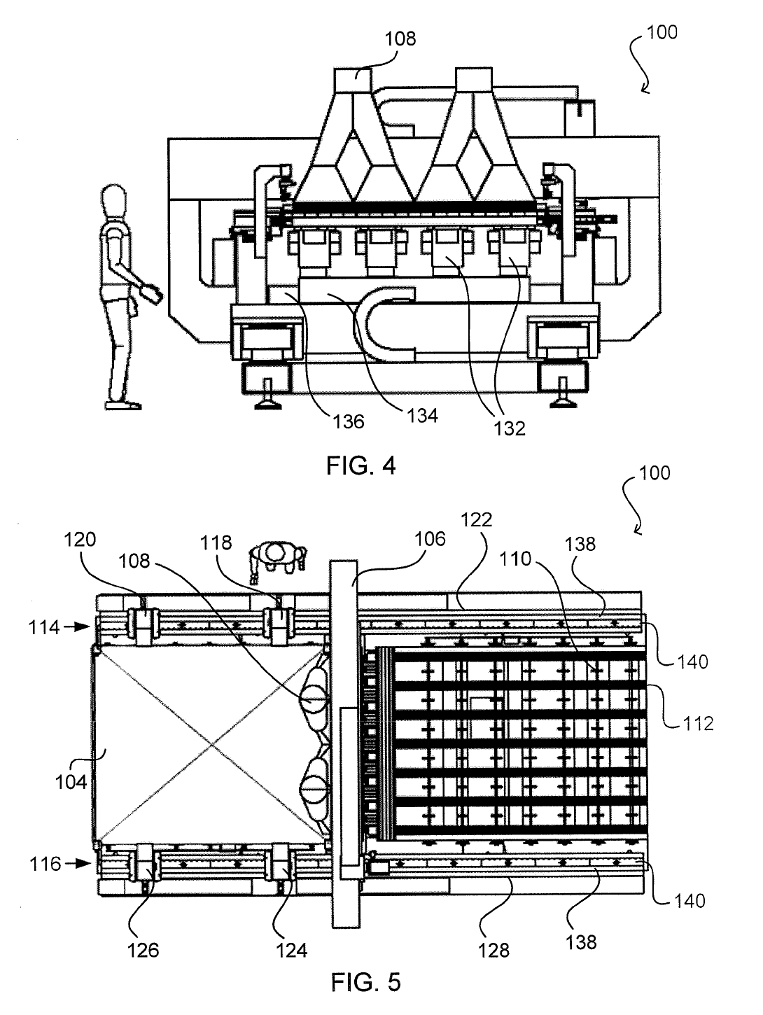

FIG. 4 illustrates an end view of the system 100, illustrating a series of laser assemblies 132 used to scribe the layers of the workpiece. While any number of laser assemblies 132 can be employed, in this specific example, there are four laser assemblies 132. Each of the laser assemblies 132 can include a laser device and elements, for example, lenses and other optical elements, needed to focus or otherwise adjust aspects of the laser. The laser device can be any appropriate laser device operable to ablate or otherwise scribe at least one layer of the workpiece, for example, a pulsed solid-state laser. As can be seen, a portion of the exhaust 108 is positioned opposite each laser assembly relative to the workpiece, in order to effectively exhaust material that is ablated or otherwise removed from the workpiece via the respective laser device. In many embodiments, the system is a split-axis system, where the stage 102 translates the workpiece 104 along a longitudinal axis (e.g., right to left in FIG. 3). The lasers and optics can be attached to a translation mechanism able to laterally translate the laser assemblies 132 relative to the workpiece 104 (e.g., right to left in FIG. 4). For example, the laser assemblies can be mounted on a support or platform 134 that is able to translate on a lateral rail 136, or using another translation mechanism, for example, a translation mechanism that may be driven by a controller and servo motor. In one system, the lasers and laser optics all move together laterally on the support 134 along with the center portion of the bed and the exhaust. This allows shifting scan areas laterally, while maintaining a small beam path and keeping the exhaust directly above the portions of the workpiece being ablated by the lasers. In some embodiments, the lasers, optics, center stage portion, and exhaust are all moved together by a single arm, platform, or other mechanism. In other embodiments, different components translate at least some of these components, with the movement being coordinates by a controller for example, as described in U.S. Patent Pub. No. 2009/0321397 A1, which has been previously incorporated herein by reference (via an above statement).

FIG. 5 illustrates a top view of the system 100 showing components of the Y-direction stages 114, 116. The Y-direction stage Y1 114 includes the X-direction stages XA1 118 and XA2 120, which translate along the Y1-stage support 122. The Y-direction stage Y2 116 includes the X-direction stages XB1 124 and XB2 126, which translate along the Y2-stage support 128. Each of the Y-direction stages 114, 116 includes a linear motor having a magnetic channel 138 disposed within the top portion of Y-direction stage supports 122, 128. Each of the Y-direction stages 114, 116 also includes a position sensing system, which includes an encoder strip 140 disposed on the respective Y-direction stage support 122, 128. Each of the Y-direction stages 114, 116 includes a reader head for monitoring the position of the Y-direction stage via reading the respective encoder strip 140.

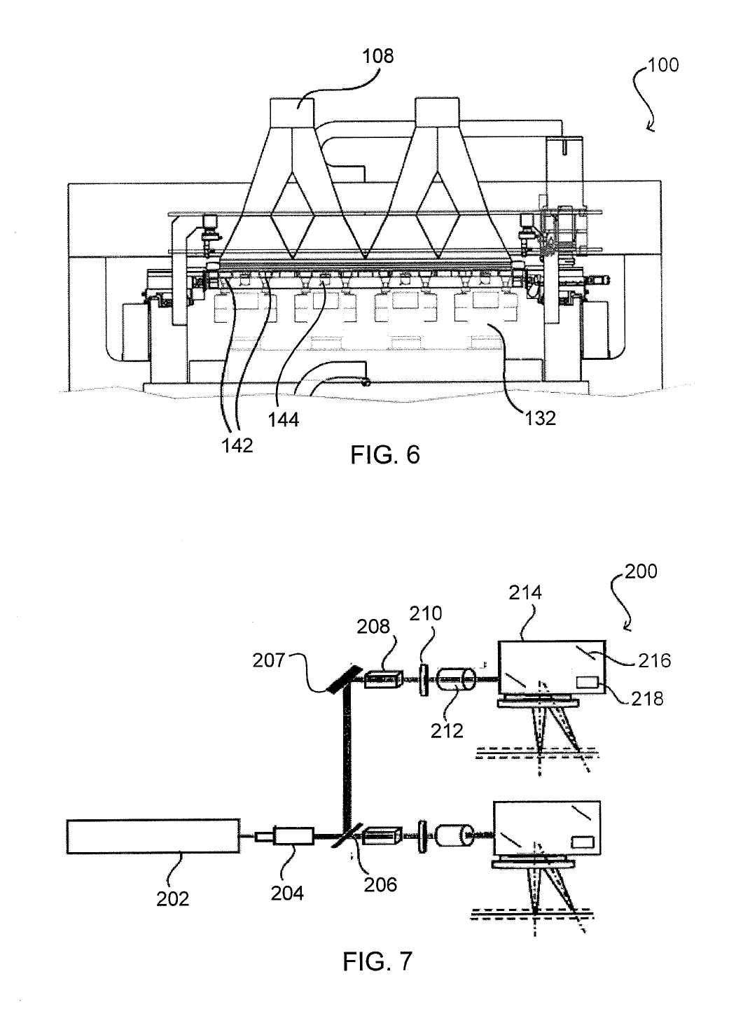

FIG. 6 is a focused view of the system 100 showing that each laser device of the system 100 actually produces two effective beams 142 useful for scribing the workpiece. In other embodiments, each laser device can be used to produce any number of effective beams, for example, two, three, or more effective beams. In order to provide the pair of beams, each laser assembly 132 includes at least one beam splitting device. As can be seen, each portion of the exhaust 108 covers a scan field, or an active area, of the pair of beams in this example, although the exhaust could be further broken down to have a separate portion for the scan field of each individual beam. Each beam in this example passes between air bearings of the bed, and the beam position between the air bearings is retained during lateral translation of the moveable center section, lasers, and optics.

Substrate thickness sensors 144 provide data that can be used to adjust heights in the system to maintain proper separation from the substrate due to variations between substrates and/or in a single substrate. For example, each laser can be adjustable in height (e.g., along the z-axis) using a z-stage, motor, and controller, for example. In many embodiments, the system is able to handle 3-5 mm differences in substrate thickness, although many other such adjustments are possible. The z-motors also can be used to adjust the focus of each laser on the substrate by adjusting the vertical position of the laser itself. A desired vertical focus of each laser can be used to selectively ablate one or more layers of the workpiece by concentrating the beam at the desired vertical position or range of vertical positions so as to produce the desired ablation. By adjusting the focus of each laser to local variations of the workpiece, more consistent line widths and spot shapes can be achieved.

FIG. 7 diagrammatically illustrates basic elements of an exemplary laser assembly 200 that can be used in accordance with many embodiments, although it should be understood that additional or other elements can be used as appropriate. In the assembly 200, a single laser device 202 generates a beam that is expanded using a beam expander 204 then passed to a beam splitter 206, for example, a partially transmissive mirror, half-silvered mirror, prism assembly, etc., to form first and second beam portions. One or more of the beam portions can be redirected by a mirror 207. In this assembly, each beam portion passes through an attenuating element 208 to attenuate the beam portion, adjusting an intensity or strength of the pulses in that portion, and a shutter 210 to control the shape of each pulse of the beam portion. Each beam portion then also passes through an auto-focusing element 212 to focus the beam portion onto a scan head 214. Each scan head 214 includes at least one element capable of adjusting a position of the beam, for example, a galvanometer scanner useful as a directional deflection mechanism. In many embodiments, this is a rotatable mirror able to adjust the position of the beam along a latitudinal direction, orthogonal to the movement vector of the workpiece, which can allow for adjustment in the position of the beam relative to the workpiece 104.

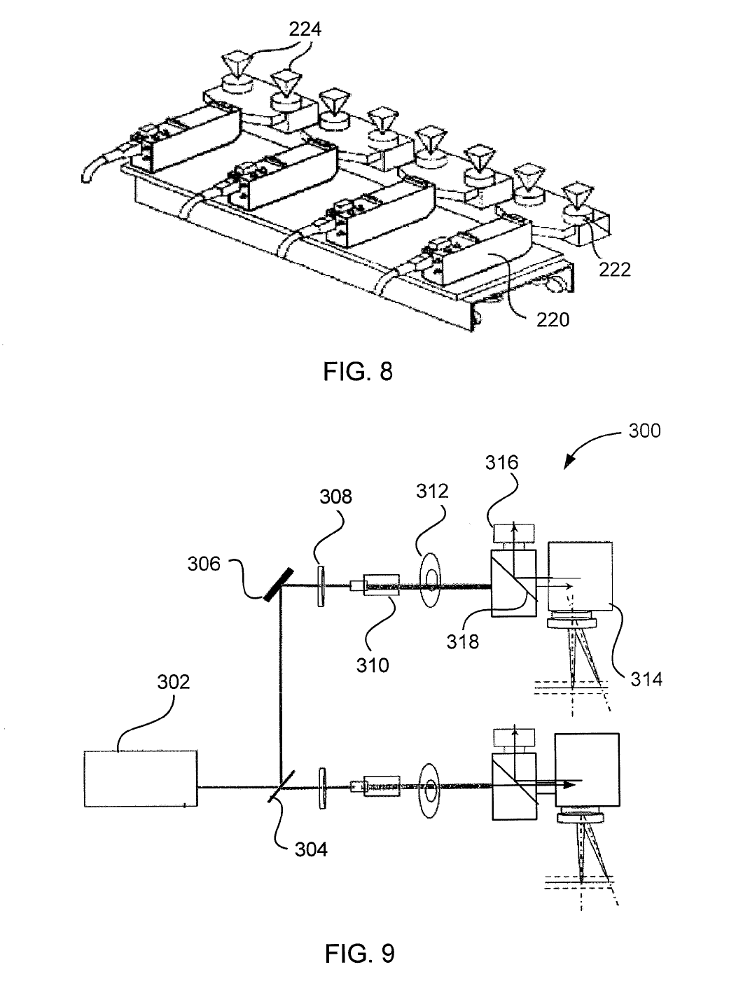

In many embodiments, each scan head 214 includes a pair of rotatable mirrors 216, or at least one element capable of adjusting a position of the laser beam in two dimensions (2D). Each scan head includes at least one drive element 218 operable to receive a control signal to adjust a position of the “spot” of the beam within a scan field and relative to the workpiece. Various spot sizes and scan field sizes can be used. For example, in some embodiments a spot size on the workpiece is on the order of tens of microns within a scan field of approximately 60 mm×60 mm, although various other dimensions and/or combinations of dimensions are possible. While such an approach allows for improved correction of beam positions on the workpiece, it can also allow for the creation of patterns or other non-linear scribe features on the workpiece. Further, the ability to scan the beam in two dimensions means that any pattern can be formed on the workpiece via scribing without having to rotate the workpiece. For example, FIG. 8 illustrates a perspective view of example laser assemblies. A pulsed beam from each laser 220 is split along two paths, each being directed to a 2D scan head 222. As shown, the use of a 2D scan head 222 results in a substantially square scan field for each beam, represented by a pyramid 224 exiting each scan head 222. By controlling a size and position of the square scan fields relative to the workpiece, the lasers 220 are able to effectively scribe any location on the substrate while making a minimal number of passes over the substrate. If the positions of the scan fields substantially meet or overlap, the entire surface could be scribed in a single pass of the substrate relative to the laser assemblies.

FIG. 9 diagrammatically illustrates a laser assembly 300, in accordance with many embodiments. The laser assembly 300 is similar to the laser assembly 200 of FIG. 7, but includes two integrated imaging devices for imaging features of the workpiece. The laser assembly 300 includes a laser device 302. The laser device 302 can include various related devices and features. For example the laser device can include an internal power meter for monitoring the power output of the laser. As a further example, the laser device can include an attenuation adjustment, for example, manual attenuation adjustment between two levels (e.g., between 5% and 95%). A beam generated by the laser device 302 can be split into first and second beam portions by a beam splitter 304, for example, a partially transmissive mirror, half-silvered mirror, prism assembly, etc.. In some embodiments, the beam splitter 304 can be manually adjusted so as to vary the relative portions of the beam generated by the laser device 302 that makes up the first and second beam portions (e.g., from 45% to 55% in a particular beam). Each beam portion passes through a shutter 308 to control the shape of each pulse. The shutter 308 can be selected to have a sufficiently fast speed necessary to accomplish a desired shaping of each pulse. For example, in some embodiments the shutter 308 can be selected to have a speed of 50 msec or less. Each beam portion also passes through a collimator 310. Various collimators can be used. For example, a 3-4× up-collimator with plus-or-minus 1 mm manual focus adjustment can be used. Each beam portion also passes through a beam shaping element 312, for example, a beam shaping element with an aperture of 2 mm, which shapes each beam portion prior to being provided to each of scanners 314, which can be similar to the scanners 214 of FIG. 7. Two imaging devices 316 are integrated with the system 300 so as to view the workpiece through the scanners 314. The light reflected from features on the workpiece enters each of the scanners 314, where it is redirected by the scanner towards a dichromatic beam splitter 318. Each dichromatic beam splitter 318 redirects the reflected light towards one of the imaging devices 316, for example, a charge-coupled device (CCD) camera or a complementary metal-oxide-semiconductor (CMOS) device. As shown, each of the imaging devices 316 can be integrated using the dichromatic beam splitter 318 so as to provide an imaging device view direction that substantially corresponds with the direction along which a separate laser beam portion is provided to each of the scanners 314. Although a range of relative positions can be practiced, an imaging device 316 can be integrated so that the center of its view and the output of the scribing laser 302 point at the same position on the workpiece being targeted by the scanner 314.

As illustrated in FIG. 9, the laser beam delivery from the laser device 302 to the scanners 314 provide free-space beam splitting and delivery. To improve the beam size consistency and laser pointing stability, the system 300 may be integrated with a fiber delivery of laser power from the laser device. To improve thermal control and reduce the size of the laser device, a remote module may be integrated with the system 300.

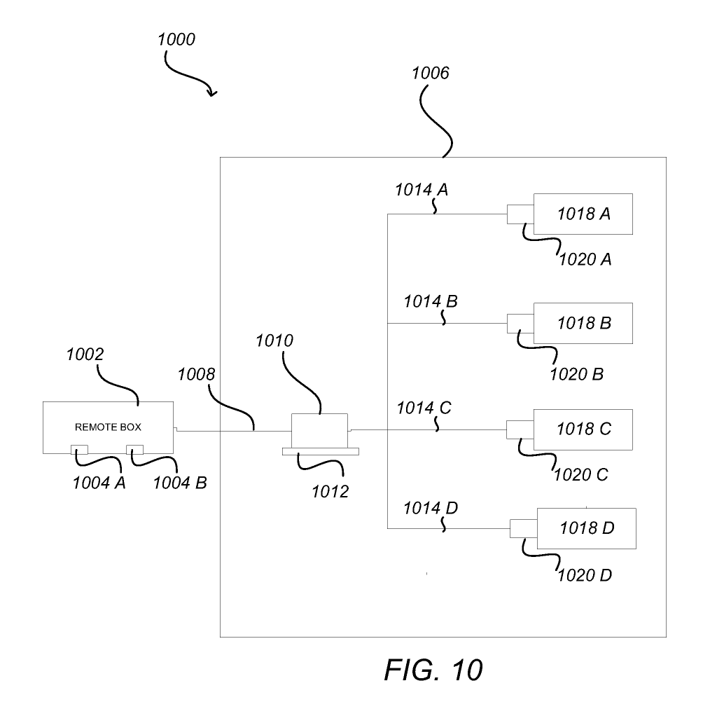

FIG. 10 shows one exemplary embodiment of a laser scribing module 1000 for laser scribing. In this embodiment, a remote box 1002 is coupled to a laser source 1010 through a long cable 1008. The cable may be 8-10 meters long or longer in some embodiments. The cable connects the remote box 1002 outside a laser scribing chamber or module 1006 to the laser source 1010 inside the chamber 1006 for power supply, cooling, and control signals. The remote box 1002 includes a controller and a chiller for cooling the laser source 1010 through a cooling plate 1012 attached to the laser source 1010. The remote box 1002 is installed outside the laser scribing chamber or module 1006 so that its footprint can be fairly large as needed. The remote box 1002 has a RS232 or I/Os port 1004A for digital transmission and an I/Os port 1004B for analog signal transmission.

The laser scribing chamber or module 1006 includes the laser source 1010, a set of beam expanders and collimators 1016A-D, and a set of fibers 1014A-D for delivery laser output from the laser source 1010 to the beam expanders 1016A-D. The set of optical fibers 1014A-D is relatively short compared to the long cable 1008, for example, such as may be about 2 m long. The coolant may be water or other fluids. The laser source 1010 is installed inside the laser scribing chamber or module 1006 so that the laser scribing chamber 1006 may have a small footprint, such as 300×300×100 mm or below and low weight.

The laser source 1010 may include a fiber laser, or a conventional DPSS laser, or a hybrid of both. In a particular embodiment, a fiber laser may have an infrared wavelength of 1050 nm to 1070 nm. The laser source 1010 may provide laser pulses having pulse width in the range of 40 ns to 150 ns, pulse energy in the range of about 50 to 200 μJ, or of at least 80 μJ, and pulse repetition frequency of at least 100 kHz. The laser beam may have beam property M₂ smaller than 1.35. Preferably, M₂ may be smaller than 1.3, the pulse width may be in the range of 40 ns to 100 ns, the pulse energy may be in the range of 80 μJ to 120 μJ, the pulse repetition frequency may be in the range of 120 kHz to 200 kHz.

In a particular embodiment, four delivery fibers 1014A-D of about a few meters long are connected to the laser source 1010 to distribute the laser output power to the scanners/focus optics 1018A-D. The delivery fibers 1014A-D may be about 1-4 meter long in one embodiment, and preferably are about one, two, or four meters long in some embodiments. Four termination modules are coupled to the end of the four delivery fibers.

The fiber termination modules 1020A-D may include power attenuators, beam shutters, optical isolators, and beam expanders or beam collimators. Each of the beam expanders and collimators (not shown) is used to get the well collimated beam with a desirable beam diameter. A well balanced beam-to-beam laser power is achieved either via the design of the laser source or via external power attenuation adjustment (not shown) to each output beam. For example, a power attenuator and a laser shutter, preferably an electro-mechanical shutter may be also attached to the end of each of the delivery fibers 1014A-D.

The laser scribe module 1006 may also include mechanical interfaces in fiber termination modules 1020A-D between the termination of the delivery fibers 1014A-D and the scanners/focusing optics 1018A-D. The mechanical interfaces 1020A-D may include a set of male connectors accurately positioning the delivery fibers and a set of female connectors mounted on the scanners 1018A-D.

Although FIG. 10 illustrates only four delivery fibers, there may be two delivery fibers and two coupled to two termination modules, or eight delivery fibers coupled to eight termination modules. One of ordinary skill in the art would recognize many other such variations, modifications, and alternatives.

One of the benefits of installing the remote box outside the laser scribe module and using water cooling to the laser source is that the thermal loading into the laser scribe module is significantly reduced. As the result, a more stable temperature control can be achieved inside the laser scribe module. Another benefit is that a centralized power supply, controller and chiller provided by the remote box also helps reduce the system cost, as only one remote box is needed to control a set of laser sources for a set of laser scribe modules. Other benefits include the fiber delivery of laser power such that laser performance, such as pointing stability and beam size consistency, is also improved compared to a free-space laser beam splitting and delivery without fiber. Furthermore, the small footprint and low weight of the laser source make the installation and maintenance easier, and thus significantly improves the serviceability and reliability of the laser scribe module. The laser scribing module with the mechanical interface also allows optical alignment to be obtained without complicated optical alignment. Because of the mechanical interface, the scanners/delivery optics can still remain inside the laser scribe module in the case of laser source replacement so that their relative positioning is not lost. This reduces the mean time to repair.

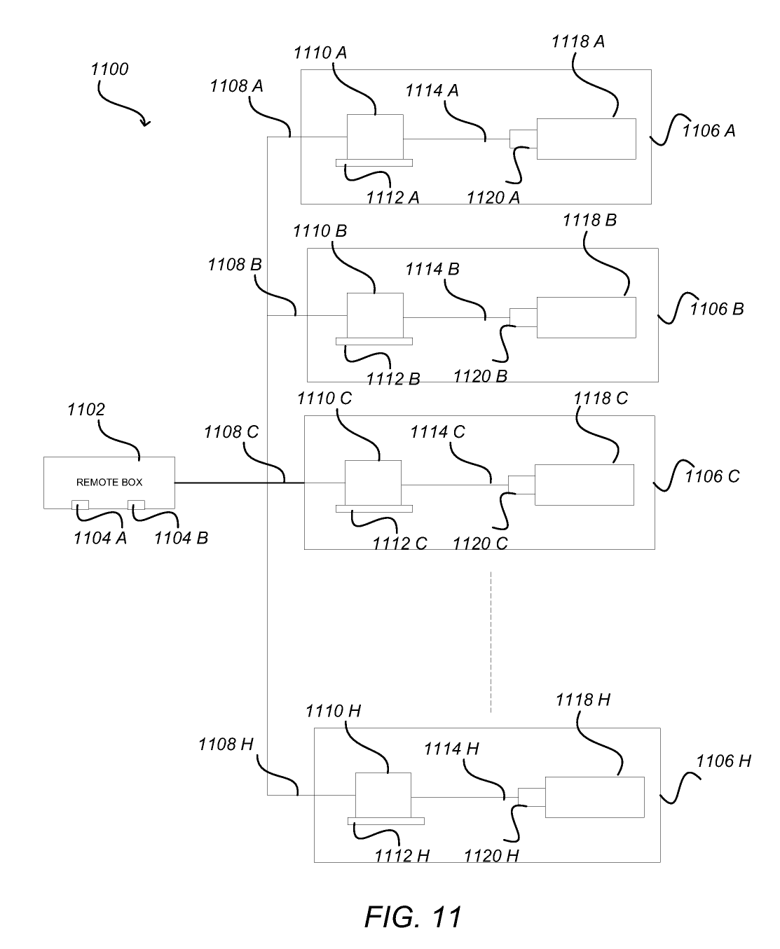

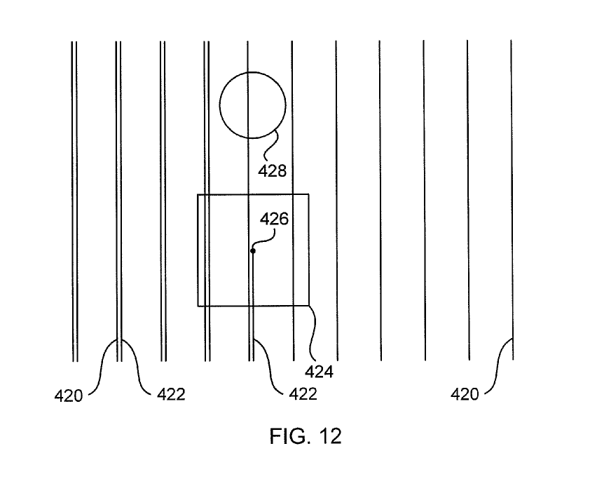

FIG. 11 illustrates another embodiment of a laser scribing system 1100. The system includes a remote box 1102 connected to laser sources 1110A-H inside laser scribe modules 1106A-H through long cables 1108A-H. The remote box 1102 includes at least a controller and a chiller (not shown), and is installed outside the laser scribe modules 1106A-H so that its footprint can be fairly large as needed. The remote box may also have an I/Os port 1104A for digital signal transmission, such as a RS232 and I/Os port 1104B for analog signal transmission. The laser source 1110 includes a master oscillator and a power amplifier. Water-cooling plates 1112A-H are attached to the respective laser sources 1110A-H for cooling. Each of the laser sources 1110A-H with each of the respective water-cooling plates 1112A-H are installed inside each of the respective laser scribe modules 1106A-H to obtain small footprint and low weight. In this embodiment, a group of 8-10 meters or longer cables connect the central remote box 1102 outside the laser scribe modules 1106A-H and the laser sources 1110A-H for power supply, cooling, and control signals. For each of the laser sources 1110A-H, one of the delivery fibers 1114A-H in range of 1 to 4 meters long is connected to one of the corresponding laser sources 1110A-H to deliver laser output power to one of the respective scanners/delivery optics 1118A-H.

At the end of the delivery fibers 1118A-H, fiber termination modules 1120A-H are correspondingly installed. Each of the termination modules 1120A-H may include an optical isolator for elimination of back reflection. Each of the termination modules may also include a beam expander and a beam collimator to get a well-collimated beam with a desired beam diameter. Each of the fiber termination modules may also include a power attenuator and a laser shutter for power control. Preferably, an electro-mechanical shutter may be attached to the end of each of the delivery fibers. The termination module may also include a mechanical interface between the termination of each of the deliver fibers and a respective scanner/optics. The mechanical interface may include a male connector accurately positioning the fiber and a female connector mounted on each respective scanner. Telecentric scan lenses 1122A-H are attached to the scanners/delivery optics 1118A-H, such as Galvo scanner heads, such that the size and shape of an image formed by such telecentric lens is independent of the object's distance or position in the field of view of a workpiece surface.

In this particular embodiment as illustrated in FIG. 11, each laser beam is produced by an individual laser. At least eight laser scribe modules are used for the laser scribe system. All eight laser scribe modules are connected to a centralized remote box for power supplier, controller and chiller.

Line sensing optics can be used to determine location data for one or more previously formed features. Such location data can be used to control the formation of subsequently formed features relative to previously formed features. For example, data indicative of one or more locations on a previously formed P1 line can be used to control the formation of a P2 line relative to the P1 line. Line sensing optics can include a light source and a camera, which detects the light reflected from the workpiece and/or scribe lines.

FIG. 12 illustrates one approach for using line-sensing optics, and shows a set of previously-formed P1 lines 420 and a partially formed set of P2 lines 422, which are being formed closely adjacent to the previously-formed P1 lines 420. A scanner field-of-view 424 and a currently targeted location 426 are shown during the formation of one of the P2 lines 422. A line-sensing optics field-of-view 428 can be used to determine location data for the P1 lines 420, for example, for the P1 line 420 next to which the P2 line 422 being formed is situated. Such location data can be used to more closely control the formation of the P2 line 422 so as to be more tightly spaced with the P1 line 420.

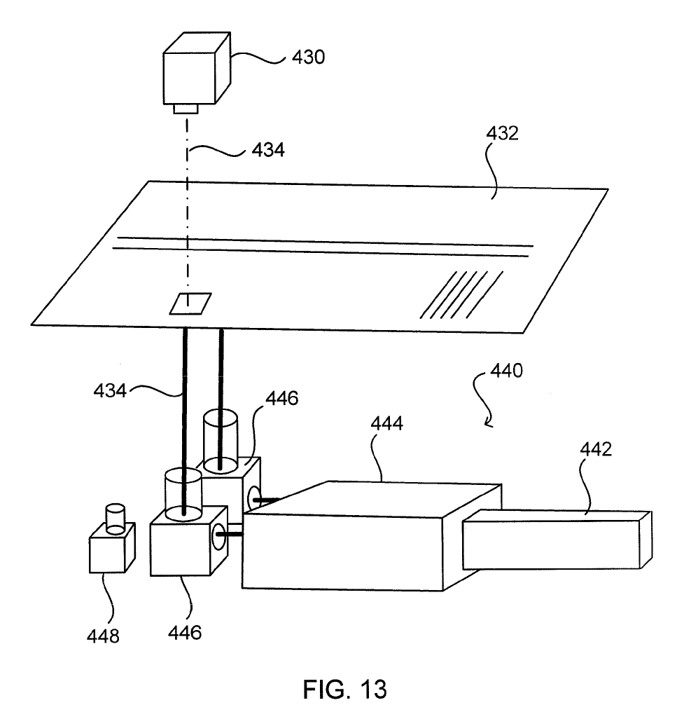

A laser-scribing system can include a number of components useful for controlling the scribing of laser lines on a workpiece. For example, as illustrated in FIG. 13, a beam viewer 430 can be used to measure the position of the output from the laser. Data from the beam viewer 430 can be used for rapid recalibration of the beam position. As illustrated, the beam viewer 430 can be positioned over a workpiece 432 so as to capture the position of a beam 434 as it passes through the workpiece 432. The expected and the actual position of the beam 434 can be compared to calculate a correction, which can provide a highly accurate adjustment for the correction of any drifts that occur. The beam measured can be projected by a laser assembly 440 that includes a laser 442, beam split optics 444, and scanners 446. As discussed above, the laser assembly 440 can be located on an optics gantry (not shown). A power meter (not shown) can also be positioned on the optics gantry for monitoring the laser power incident on the glass. A microscope (not shown) can also be used. A primary function of the microscope is calibration and alignment of the glass. The microscope can also be used to observe the scribe quality and measure the size of ablation spots. A line sensor 448 can also be used to generate location data for previously formed features. The line sensor 448 can be located in a number of locations from which it can view the previously formed features, for example, beneath the workpiece 432 as illustrated.

Although the scribed lines can be imaged using the imaging device 316 after scribing as illustrated in FIG. 9, it is desirable to have an in-situ device to monitor the scribed lines. For example, electrical isolation monitoring can be added to a laser scribe system in order to monitor the isolation properties of a workpiece during the patterning process. At least one ohmmeter may be used to measure the electrical isolation properties in-situ, such that any lines containing gaps or otherwise improperly formed can be re-scribed or repaired while the workpiece is still in the system. Such electrical isolation monitoring can assist in quickly locating and repairing the scribed lines which do not meet a processing criteria. The information of resistance measurement can be collected and analyzed for trending and process control.

FIG. 14A shows an example of a device that can be integrated into the system 300 for monitoring a resistance with respect to various scribed lines. A monitoring system 1400 in one embodiment includes an in-situ ohmmeter 1404 connected to a control or monitoring component, which can be used to monitor system performance. The in-situ ohmmeter 1404 can ensure that the isolation lines scribed into the workpiece effectively isolate the solar cells or other such regions on the workpiece. For example, the ohmmeter 1404 can measure the resistance across an isolation line that is intended to substantially isolate regions on either side of the isolation line. Since the resistance measurement can be performed in-situ, if an isolation line is determined to be formed improperly, the scribing device can locate a defect along the isolation line and repair the defect without the workpiece being removed from the system 1400, which makes it easier and faster to locate and repair the defect. If the electrical isolation of the scribed lines is determined to be poor beyond a specified threshold, the workpiece can simply be removed from process such that no additional time or resources are dedicated to the workpiece. The workpiece can simply be junked or recycled. Further, the resistance values can be monitored over time to track variations in resistance and perform trending analysis, which can help predict problems with scribed isolation lines on subsequent workpieces and allow for adjusting system parameters to avoid these problems.

FIG. 14B illustrates an example device for measuring isolation resistance of P3 lines on the workpiece. In one embodiment, for measuring resistance across a scribed line, an ohm meter may have a probe 1402A on one side 1404A of the isolation scribed line 22 and another probe 1402B on the other side 1404B of the isolation scribed line 22. The measured resistance between the two probes can indicate the effective electrical isolation of the scribed line 22. In another embodiment, one probe may be placed on one end of a scribed line, and another probe may be placed on another end of the scribed line, and the resistance along the scribed line can be measured. Such measurements may detect any gap or missing along the scribed line.

Because a P3 scribed line is through a conductive metal layer, the resistance measurement is more sensitive for detecting defects in a P3 scribed line than a P1 or P2 line, which are scribed through a material of lower conductivity or higher resistivity. For a P3 isolation line 22 to be scribed through the three layers including the metal layer 20, the amorphous silicon layer 18 and the TCO layer 14, about 1.0 kilo ohm may be an appropriate threshold. For a P1 line 16 in the TCO layer 14, about 1.0 mega ohm may be an appropriate threshold. For a P2 line 19 in the amorphous silicon layer 18, about 1.0 mega ohm may be an appropriate threshold. For a P3 interconnection line 22 through the metal layer 20 and the amorphous silicon layer 18, about 1.0 mega ohm may be an appropriate threshold.

If the resistance of a scribed line is determined to be below the threshold, at least a portion of the scribed line can be re-scribed without removing the workpiece from the system. The monitoring information can also be used to perform trending, etc., as discussed above, to predict when the process parameters might need to be changed to prevent problems, etc.

FIG. 15 illustrates an integration of a discharge mechanism within the laser scribing system 300 as illustrated in FIG. 9. One or more ionizers 1502 may be used at or near the entrance of the workpiece into the scribing system 1500 to minimize the presence of electrostatic charge on the workpiece as shown in FIG. 15. The ionizer 1502, such as a cartridge ionizer, may be near the entrance of the workpiece and/or near the lasers where the material is ablated. Other such locations can be used as well within the scope of the various embodiments. Since a statically charged substrate can tend to attract particles, it can be desirable to include at least one discharge mechanism (ionizer) to discharge the workpiece and to prevent the collection of particles. There are many commercially available ionizers. For example, a cartridge ionizer may use high voltage to ionize air molecules. The cartridge ionizer can be designed to generate positive ions or negative ions. Scribing materials or airborne particles may be attracted to the workpiece in an effect similar to static electricity. These ions can be de-ionized by using the ionizer. The cartridge ionizer can be used close to the position where scribing material is removed or ablated from the surface of the workpiece. These or other discharge mechanisms can be integrated with the scribing system 1500.

A combination of air bearings, properly selected optics, and properly controlled lasers of an appropriate frequency in some embodiments allows the workpiece to move on the stage and to be processed at a relatively high rate, such as a rate of about 2 m/s. Such a rate of 2 m/s is an important advantage at the present time. In addition to the use of air bearings, touchdown rails can be used in conjunction with the air bearings to prevent the workpiece or glass from accidentally contacting the air bearings and scratching the glass. The proper operating conditions, calibration, selection of elements and sizes can be important as well.

It is understood that the examples and embodiments described herein are for illustrative purposes and that various modifications or changes in light thereof will be suggested to a person skilled in the art and are to be included within the spirit and purview of this application and the scope of the appended claims. Numerous different combinations are possible, and such combinations are considered to be part of the present invention.

What is claimed is:

1. A laser system for laser scribing comprising:
a laser module comprising a laser source and a cooling plate, the laser module being operable to remove material from at least a portion of a workpiece;
a plurality of termination modules coupled to the laser module through a plurality of optical fibers, each of the termination modules comprising a mechanical interface, the mechanical interface being coupled to a respective optical fiber;
a plurality of scanning devices operable to control a position of the output from the laser, each of the scanning devices being coupled to a respective mechanical interface; and
a remote module coupled to the laser module through a cable, the remote module comprising a controller and a chiller.

2. The laser system of claim 1, wherein the termination module comprises a beam expander.

3. The laser system of claim 1, wherein the termination module comprises a beam collimator.

4. The laser system of claim 1, wherein the termination module comprises a beam isolator.

5. The laser system of claim 1, wherein the termination module comprises a power attenuator.

6. The laser system of claim 1, wherein the termination module comprises a beam shutter.

7. The laser system of claim 1, wherein the remote module comprises a first I/O port for digital signal transmission to the laser module and a second I/O port for analog signal transmission to the laser module.

8. The laser system of claim 1, wherein the remote module comprises a power supply.

9. The laser system of claim 1, wherein the cable is at least 8 meter long.

10. The laser system of claim 1, wherein the optical fiber is 2 meter long.

11. The laser system of claim 1, wherein the laser module comprises a beam splitter, the splitter being coupled to the plurality of the optical fibers.

12. A laser system for laser scribing comprising:
at least one laser module operable to remove material from at least a portion of a workpiece;
at least one scanning device operable to control a position of the output from the laser module; and
a discharge mechanism adjacent to at least one of the scanning device and the workpiece, the discharge mechanism operable to discharge a surface of the workpiece.

13. A laser system for laser scribing comprising:
at least one laser module operable to remove material from at least a portion of a workpiece;
at least one scanning device operable to control a position of the output from the laser module; and
a resistance measurement device for resistance measurement operable to be coupled to the workpiece for in-situ measurement of electrical isolation of scribed lines on the workpiece.

14. A laser system for laser scribing comprising:
a plurality of laser modules, each of the laser modules comprising a laser source, the laser modules being operable to remove material from at least a portion of a workpiece;
a plurality of termination modules coupled to the plurality of laser modules through a plurality of optical fibers, each of the termination modules comprising a mechanical interface, the mechanical interfaces being coupled to the respective optical fiber;
a plurality of scanning devices operable to control a position of the output from the laser, each of the scanning devices being coupled to the respective mechanical interface; and
a remote module coupled to the plurality of laser modules through a cable, the remote module comprising a controller.

15. The laser system of claim 14, wherein each of the laser modules further comprises a cooling plate.

16. A method for fabricating a solar-cell assembly comprising:
providing a workpiece comprising a substrate and at least one layer including scribed interconnect lines;
scribing a plurality of isolation lines into the at least one layer;
measuring electrical isolation resistance of at least one of the plurality of isolation lines; and
determining if the electrical isolation resistance at least meets a threshold.

17. The Method of claim 16, further comprising:
re-scribing a portion of the each measured isolation line if the electrical isolation resistance is below the threshold.

18. The method of claim 16, wherein said substrate comprises glass.

19. The method of claim 16, wherein a first layer comprises a transparent-conductive-oxide (TCO).

20. The method of claim 16, wherein a second layer comprises silicon.

21. The method of claim 16, wherein a third layer comprises a metal.

22. The method of claim 16, wherein said scribing isolation lines comprises directing a series of laser pulses up through the substrate, wherein the series comprise laser pulses having 50 to 200 μJ of energy.

23. The method of claim 16, wherein said scribing isolation lines comprises directing a series of laser pulses up through the substrate, wherein the series comprise laser pulses having a pulse width of 75 to 100 nanoseconds.
